(19) United States
(12) Patent Application Publication
(10) Pub. No.: US 2006/0279974 A1
(43) Pub. Date: Dec. 14, 2006

(54) AC line isolated DC high frequency low power converter

(76) Inventors: Gary Hanington, Elko, NV (US); Mira Kurka, Elko, NV (US)

Correspondence Address: Gary Hanington, P.O. Box 1038, Elko, NV, 89803, US

(21) Appl. No.: 11/148,867

(22) Filed: Jun. 8, 2005

(51) Int. Cl. H05K 7/20

(52) U.S. Cl. 363/141

(57) ABSTRACT

Circuit arrangements and methods are disclosed for providing a source of low power DC, direct and isolated from the main AC line. Applications of this circuitry include battery chargers and air ionizers. In this design, a high frequency ferrite transformer 16 is driven by signals created from a bilaterally conducting two state device 12 operating in series with a capacitor 15. Utilizing a bilaterally conducting two state device 12, capacitor 15 is alternately charged positive and negative to a certain voltage level depending on the characteristics of 12. The device 12 will see an increasing voltage across it due to the increasing magnitude of the input AC waveform. When the voltage across 12 reaches the breakover voltage of the device, Vbo, it rapidly changes state from a blocking condition to one of full conduction. When this occurs the stored energy present in the capacitor 15 causes fast rise time pulses rich in high frequency harmonics to be impressed across the primary of the transformer 16 which has been designed with an operating frequency of 20 kHz or greater. A simple rectifier stage on the secondary consisting of 18 will convert the AC pulses generated on the secondary of 16 to the desired DC output voltage where it is filtered with capacitor 19. For high voltage applications, a multi stage, Cockroft Walton voltage multiplier circuit may be utilized on the secondary of 16.

### BACKGROUND OF THE INVENTION

Field of Invention

The present invention relates generally to electrical power supplies which operate from a main AC line power source. More particularly, the present invention relates to a cost-, weight- and volume-effective discrete circuit arrangement for providing a source of isolated voltage, either low or high potential at low output power levels.

Power converters which operate off of the AC main line are used throughout the world to provide voltages and currents necessary to operate electrical and electronic systems. These power supplies are commonly referred to as main AC line power supplies. Construction of main AC line power supplies is well known in the art, having been in existence since the early 20^{th} century for applications such as battery chargers and welders and later for powering radios, televisions and computers. At present, most AC main line power supplies fall into two different categories. One group converts and isolates the 60 cycle AC waveforms to other voltages using a laminated iron transformer. In this manner the desired output voltage may be galvanically isolated from the main AC line circuit for safety reasons. Into this group fall devices such as the common battery charger for cell phones. It is important for safety considerations that the output voltages from this converter be fully isolated from the AC main line, otherwise a lethal circuit may be set up between the output of the power supply and earth ground that the user may come in contact with (such as a water pipe).

A second type of power converter has emerged within the last two decades which offers lighter weight efficiency than the previous type. This is the switching power supply. It, too, offers isolation from the AC main line and has found uses in computers and entertainment systems. Switching power supplies owe their weight and size efficiency to the use of high frequency ferrite converter transformers which do not rely on laminated iron for a core material. They can be made lightweight and highly efficient due to the absence of eddy current flow which is ever present in laminated devices.

Some AC main line power supplies are used for low power applications. For example, a trickle battery charger, which is to be left on to maintain the charge level in a standby battery needs only to supply a few milliwatts of power to compensate for the natural decline in a battery's condition and keep the battery at ready status. Many high voltage applications require only a low power system. Air purifiers which remove particulate matter in an air stream by electrostatically charging metallic collection plates upon which the foreign matter is deposited, only require a few milliwatts for operation.

A typical prior art AC main line power supply of the first type is shown in FIG. 1. Here a main AC line voltage is coupled into a laminated iron transformer 2 primary having many turns of wire to keep magnetizing currents to an acceptable level. Transformer 2 has a secondary winding which converts the input AC line voltage, usually 120 VAC in the United States, to a desired lower output voltage. The stepped down voltage is rectified by diode 3 and smoothed in waveform by filter capacitor 4. For an application such as a simple battery trickle charger, the DC voltage may be regulated and limited by other circuitry not shown. High voltage power supplies which provide a stepped up voltage at low power often require a separate DC to DC converter within the design operating at a high frequency. In this way, dangerous stored energy in the filter stage may be kept at a minimum.

As mentioned earlier, another form of prior art AC main line power supply is the switching supply. Recently these have found use in low power battery chargers for cell phones. Here the bulky and heavy laminated iron transformer is replaced with a low cost miniature transformer whose core is made of ferrite material. The switching power supply converts the AC line voltage to a high DC voltage by direct rectification and filters this rectified waveform with a large energy storage capacitor. From this point on, this design utilizes high voltage switching transistors to drive the high frequency ferrite transformer. The use of high frequency power conversion allows the use of smaller magnetic devices and filtering capacitors at the expense of a relatively complicated control and driver circuitry.

In the prior art circuitry arrangements discussed above, the 60 cycle main AC line iron laminated transformer can account for substantial weight, size and cost of the power supply. This is due to the fact that the cross sectional area of the transformer is inversely proportional to the frequency of operation. Since operation at a fixed line frequency of 50 or 60 Hz is usually the case, the only technique for size reduction in the laminated iron transformer is to increase the number of primary windings, which unfortunately only increases cost and Ohmic power losses. Switching power supplies can use a smaller and lower cost ferrite transformer because their operating frequency is usually set above 20 kHz.

As will be described in the following detailed description, the present invention overcomes many of the cost, size, weight and complexity problems associated with prior art low power AC main isolated power supplies by replacing the costly laminated iron transformer with a lower cost, smaller size, and higher efficiency ferrite transformer and replacing switching converter components with an inexpensive bidirectional two state device. Examples of this device are a SIDAC, DIAC or even a gas plasma lamp. Solid state SIDACs are bi-directional devices primarily intended for use in arc or gas plasma illumination applications. SIDACs are mainly used for spark initiation in high pressure gas discharge lamps. The singular conduction characteristics of a bi-directional two state device may be advantageously adapted to the present invention as will be described in more detail in the following paragraphs. As a result of the replacement of the laminated iron transformer, or replacement of complex drive switching circuitry with the circuitry in this invention, low power AC main line to DC isolated converters, both low and high voltage can be manufactured at significant cost, volume and weight savings.

Because of their unique advantage in generating switching waveforms, SIDACs for use in power supplies are found in prior art designs. FIG. 2 shows a low power RC relaxation oscillator power supply which operates from a DC potential that utilizes a SIDAC for waveform generation in the frequency range of 500 to 5 kHz. Due to the placement position of the SIDAC, any brief short circuit on the output of the power supply would quench oscillations and latch the SIDAC into constant forward conduction, a mode from which it cannot recover. In addition, this prior art design requires a DC input for operation.

### Objects and Advantages

The invention that will be described in the following paragraphs has several advantages over prior art. First, this converter operates directly with incoming AC main line voltage without the need for initial DC conversion as in prior art SIDAC designs. Secondly, it utilizes a ferrite type transformer which offers reduced weight, lower cost, and simplicity of construction over laminated iron transformers. Third, since high conversion frequencies are used in this power supply, it is easy to construct high voltage power supplies with low output ripple and high voltage regulation with large step up ratios utilizing multi-stage voltage multiplier circuits. This is usually precluded in simple 60 Hz designs due to size limitations of high voltage capacitors. Finally, the use of a series capacitor in this design allows for complete commutation of the bi-directional two state device, unlike prior art designs. It cannot latch up if operated into a short circuit.

### SUMMARY

Circuit arrangements and methods are disclosed for producing low power AC to DC voltage conversion direct and isolated from the AC main line. In the case of a step down converter, the circuitry consists of a high frequency ferrite transformer being driven by waveforms produced by the combination of a bi-directional two state device, e.g. a DIAC or SIDAC, in series with a capacitor. The changing AC main line waveform allows the electronic device to breakover at certain points in time providing high frequency pulses, rich in harmonics to drive the primary of the ferrite transformer. The transformer provides a specific reduction in voltage corresponding to its turns ratio. The secondary of the ferrite transformer drives a rectifier stage and ripple removing capacitor arrangement and provides an output voltage across the terminals as shown.

The operation of this invention may be easily understood by examination of FIG. 3. When the AC main line voltage is applied to the converter, the voltage on the capacitor in series with the transformer primary will, periodically, and in phase with the AC main frequency, switch from one potential to another, in square wave fashion, and transfer power through the ferrite transformer at those points of step changes. The high switching speed of the bidirectional two state device allows waveforms to be developed across the primary of the transformer whose frequency depend upon the reactive components of the transformer and the impedance of the reflected reactive components of the output circuitry. These primary waveform oscillation frequencies do not depend upon the value of the series capacitor and this converter is recoverable from any short circuit placed on its output.

In a second embodiment, a high voltage converter is shown in FIG. 4, which provides a step up voltage isolated from the AC main line. Here the output circuitry of the converter utilizes a multi stage voltage multiplier circuit which, along with a step up transformer, increase the output DC level many times above the magnitude of the waveform of the AC main line.

In either case, the AC line voltage is converted to an isolated DC voltage by using the singular properties of the bidirectional two state device, without the use of resistors or rectifier diodes on the AC input primary side of the converter. The high frequency pulses generated by this switching technique drive a compact ferrite transformer which provides power to a rectifier/capacitor output stage.

### DRAWINGS—FIGURES

FIG. 1: Illustrates prior art arrangement of an AC line operated DC power converter utilizing a laminated iron core transformer.

FIG. 2: Illustrates a prior art step down DC line operated trickle power supply utilizing a SIDAC.

FIG. 3: Illustrates the AC line isolated DC high frequency low power step down converter FIG. 4: Illustrates the AC line isolated DC high frequency low power step up converter.

FIG. 5: Displays a typical wave form present across the primary of the ferrite transformer.

FIG. 6: Shows a typical waveform present across the capacitor which is in series with the bidirectional two state device having a breakover voltage of 110 volts and the AC main line wave form.

FIG. 7: Displays a typical wave form present across the capacitor which is in series with the bidirectional two state device having breakover voltages of approximately 40 volts and the AC main line wave form.

FIG. 8: Illustrates an AC line isolated DC high frequency low power converter with multiple output voltages.

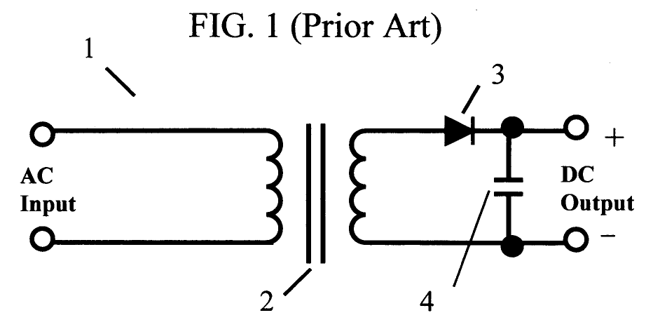

### DETAILED DESCRIPTION-FIGS. 1-5

The present invention discloses circuit arrangements and methods for construction of an AC main line operated isolated power supply utilizing a bi-directional two state device such as a SIDAC, DIAC or gas plasma lamp. In the following description, for purposes of explanation, specific numbers, times, frequencies, dimensions, waveforms, and configurations are set forth in order to provide a through understanding of the present invention. However, it will be apparent to one skilled in the art that the present invention may be practiced without these specific details.

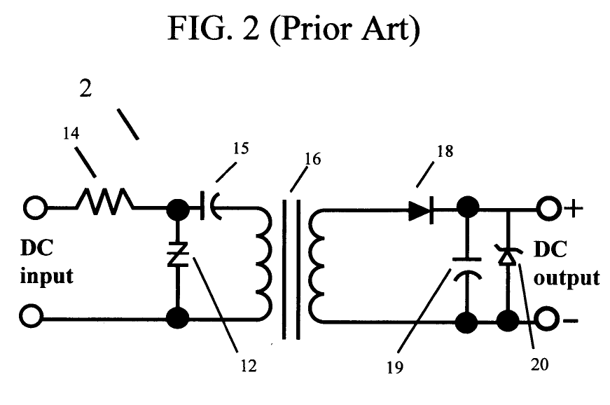

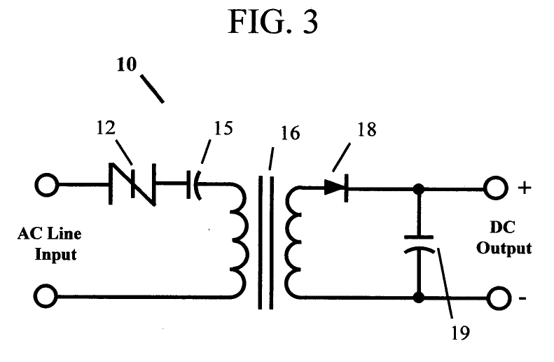

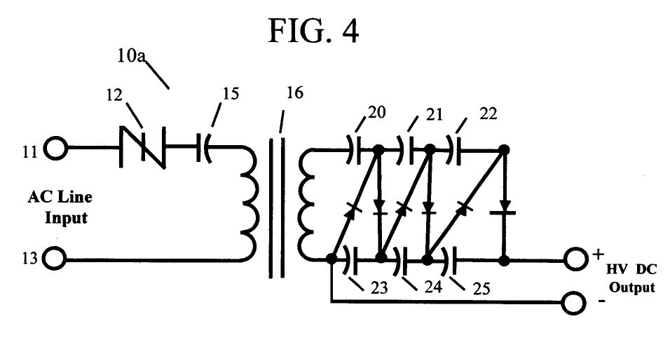

Reference is now made to FIG. 3, wherein is shown a schematic of an AC line isolated step down power supply arrangement 10 according to the first embodiment of the present invention. This power converter is shown as disposed within a battery charging system (not shown), for example and without limitation a cell phone charger. As shown in FIG. 3, the arrangement 10 consists of several essential components of the prior art arrangement shown in FIG. 2. However, the arrangement of 10 of the present invention is principally distinguished from the prior art by the inclusion of the bidirectional two state device 12 in series with the transformer primary 16 and pulse coupling capacitor 15.

In FIG. 3, arrangement 10 is coupled to receive an unregulated AC voltage. This unregulated AC voltage, typically but not limited to waveforms of +169 volts peak to −169 volts peak, with a frequency typically of 60 Hz, with respect to the neutral line, is applied to the bidirectional two state device, 12. This semiconductor device 12 having first and second terminals is positioned in such a manner that the electrical current path next flows through a coupling capacitor 15 and after this component through the primary of a ferrite transformer 16. In one presently practiced embodiment, the bi-directional two state device is manufactured by Teccor and sold under the trade name of SIDAC, more particularly the K1200E device. This device has a listed minimum breakover voltage of 110 volts and a maximum current of 1 Ampere. This breakover voltage is symmetrical in both positive and negative directions, wherein the SIDAC 12 will switch to its low impedance on state when subjected to momentarily impressed voltage above the breakdown potential Vbo. The SIDAC 12 is further characterized by having a low on state impedance with large current carrying capacity. That is, once the breakover voltage has been reached and exceeded, the SIDAC 12 will rapidly switch states and conduct large amounts of current with very low resistance to the current flow. Further, the low on resistance will remain in this state until the current through the device has been reduced to below a level called the device holding current, which is usually in the milliampere region. This will naturally occur due to the fact that capacitor 15 is in series with the SIDAC 12 and currents will naturally reach zero and reverse polarity due to the driving AC waveform passing through a zero magnitude point. This circuit is commutated by the input waveform and cannot latch into one sustained mode.

With further reference to FIG. 3, this series capacitance 15 will charge up in potential due to the incoming AC waveform until the voltage across the SIDAC 12 has exceeded its breakover voltage. Once this occurs, the SIDAC 12 switches on and a pulse of current is caused to flow in the series circuit. This pulse of current will develop a voltage across the primary of the transformer 16 owing to the impedance of the primary and reflected load. This voltage is stepped down at the secondary in the circuit shown in FIG. 3.

In the present invention, it is anticipated that the transformer 16 comprises a miniature ferrite transformer having primary and secondary windings which can couple the voltage pulse developed across the primary to the secondary and achieve the required voltage multiplication or division factor. In the design presently practiced, the capacitor 15 driving the transformer 16 consists of a 0.01 microfarad device. The transformer 16 of this practiced device consists of an 1811 ferrite pot core of material 3C81, having a primary of 24 turns and a secondary of 3 turns offering a voltage reduction factor of 8 to 1. The primary impedance of this transformer 16, in the step down device presently practiced has been measured at approximately 1.0 mH.

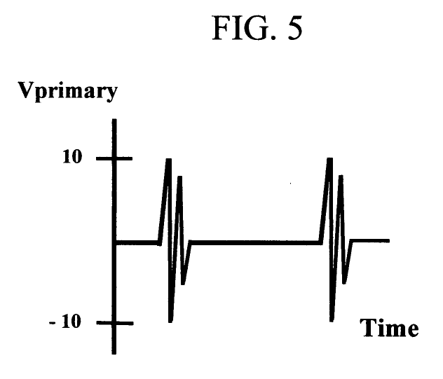

Referring to both FIG. 3 and FIG. 5, the voltage pulse produced across the primary is shown. It can be seen that this pulse is oscillatory in nature. It can be shown that the frequency of this waveform does not depend upon the series capacitance of the circuit 15 but on the capacitance reflected from the secondary as developed across the primary winding. This oscillatory waveform is of a sufficiently high frequency to easily drive the primary of the ferrite transformer 16 and is usually found to be above 20 kHz, depending to some extent on the load on the output of the converter 10. FIG. 5 shows that in the device presently practiced the voltage across the primary is in the vicinity of 20 volts peak to peak, depending again on the load applied to the output of the converter. With this in mind, and referring to FIGS. 3 and 5, the voltage across the capacitance 15 during steady state operation can be understood to be a periodic square wave in nature owing to the switching action of the SIDAC 12.

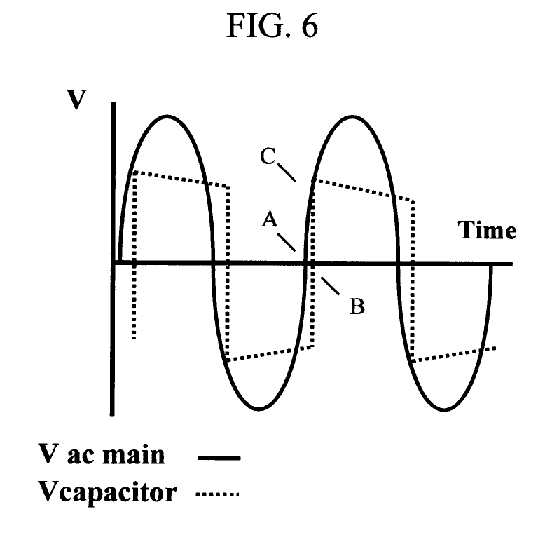

FIG. 6 illustrates the operation of this invention. Here displayed is both the incoming AC main line voltage and the voltage at the junction of capacitor 15 and SIDAC 12. All voltages are with respect to the AC return line.

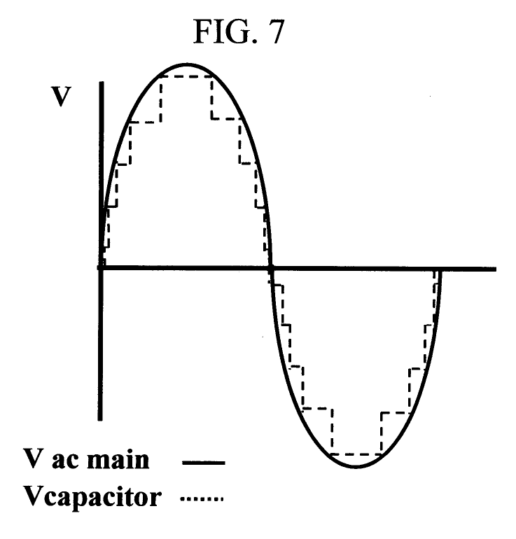

Consider point A in time. The AC main line is beginning to increase positively in magnitude from its zero crossing point. The capacitor 15 has an initial negative voltage across it from previous cycles. Thus as time moves on, the AC main line increases in magnitude increasing the voltages across the SIDAC until at time B, the voltage across the SIDAC has reached the breakover voltage Vbo and the device turns on and conducts. When the SIDAC switches on, its impedance drops to a low value and the capacitor charges up to a potential given at point C. The capacitor maintains this voltage and the cycle repeats its operation, only this time with a negative voltage AC wave. Due to this, it is seen that the switching from blocking to conducting occurs twice every AC cycle or at a 120 Hz rate for a 60 Hz driving waveform. By selection of SIDAC parameters, especially breakover voltage, additional pulses may be obtained in the operation of this converter during the course of one sine wave. Referring to FIG. 7, by utilizing a lower breakover voltage SIDAC a multitude of pulses may be obtained that drive the primary of the ferrite transformer 16. The effect of this is to increase the effective frequency of operation of the converter. This reduces the ripple voltage on the DC output and increases the voltage regulation of the converter at the expense of lower power level conversion.

Referring to FIG. 4, a high voltage may be generated in another embodiment of this basic converter. Here, the primary side of the transformer consists of the same mechanism as the low voltage power supply and operates in the same fashion. By utilizing a step up transformer, a series of high voltage oscillatory waveforms are produced at the output of the secondary of the transformer. By driving a Cockroft Walton series multiplier or other multiplier forms, on which only the former is shown in FIG. 4, a high voltage output, may be obtained from this converter. This use of small value capacitors in the multiplier section of this output stage is feasible because the oscillatory frequency of operation is above 20 kHz in the presently practiced embodiment of the present invention.

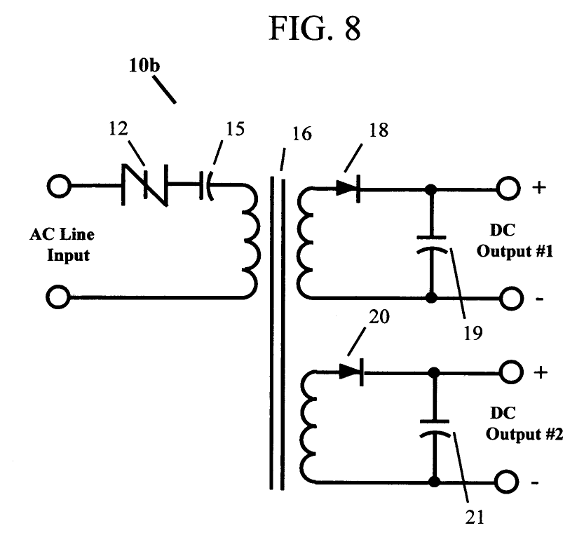

Referring to FIG. 8, multiple isolated output voltages may be generated at the same time in another embodiment of this basic converter.

Unlike prior art embodiments described above and embodied in hardware, the present invention substantially overcomes the cost, weight and volume constraints of prior art that provided isolated DC outputs at low power from the AC main line. Whereas prior art low power converters utilize laminated iron transformers or intricate switching stages to generate the output voltage and current, the bidirectional two state device in combination with the series capacitor and high frequency transformer deliver similar performance at a great savings in cost, volume, and weight. A further benefit of the present invention is the increase in reliability achieved by using fewer parts to accomplish the same result.

We claim:

1. An AC input line operated low power isolated high frequency power supply for generating voltages and currents, said power supply comprising:
a) The bidirectionally conducting two state electronic device with breakover characeteristic means coupled to an AC source for switching electrical energy,
b) The charge storage means coupled to the bidirectionally conducting two state electronic device with breakover characteristic for enabling said bidirectionally conducting two state electronic device to conduct and isolate, thereby generating a periodic oscillatory switching waveform having a plurality of alternating polarity profiles,
c) The voltage transforming means coupled to said charge storage means and said bidirectionally conducting two state electronic device with breakover characteristic for converting said periodic oscillatory switching waveform into an isolated periodic oscillatory switching waveform,
d) The rectificaton means coupled to said voltage transforming means for converting said isolated periodic oscillatory switching waveform into a waveform with a net DC component,
e) The filtering means coupled to said rectification means for reducing AC ripple component on said waveform with net DC component and converting said waveform with a net DC component into voltage and current outputs comprising said low power isolated high frequency power supply.

2. The AC line input low power isolated high frequency power supply as set forth in claim 1, wherein said bidirectionally conducting two state electronic device with breakover characteristic means comprises a SIDAC having a breakover voltage Vbo, said SIDAC having a high impedance non conducting state when the potential across said device is less than Vbo, said SIDAC further comprising a switch to a low impedance conducting second state when the potential across said device is raised above Vbo.

3. The AC line input low power isolated high frequency power supply as set forth in claim 1, wherein said bidirectionally conducting two state electronic device with breakover characterisic means comprises a DIAC having a breakover voltage Vbo, said DIAC having a high impedance non conducting state when the potential across said device is less than Vbo, said DIAC further comprising a switch to a low impedance conducting second state when the potential across said device is raised above Vbo.

4. The AC line input low power isolated high frequency power supply as set forth in claim 1, wherein said bidirectionally conducting two state electronic device with breakover characteristic means comprises a three layer trigger diode having a breakover voltage Vbo, said a three layer trigger diode having a high impedance non conducting state when the potential across said device is less than Vbo, said a three layer trigger diode further comprising a switch to a low impedance conducting second state when the potential across said device is raised above Vbo.

5. The AC line input low power isolated high frequency power supply as set forth in claim 1, wherein said bidirectionally conducting two state electronic device with breakover characteristic means comprises a gas plasma tube having a breakover voltage Vbo, said gas plasma tube having a high impedance non conducting state when the potential across said device is less than Vbo, said a gas plasma tube further comprising a switch to a low impedance conducting second state when the potential across said device is raised above Vbo.

6. The AC line input low power isolated high frequency power supply as set forth in claim 1, wherein said charge storage means comprises a first capacitor for providing a location in the circuit for accumulation of charge with increase of potential across this said device.

7. The AC line input low power isolated high frequency power supply as set forth in claim 1, wherein said voltage transforming means comprises a ferrite transformer providing isolation ability having a primary side and secondary side said voltage transforming means producing said periodic oscillatory switching waveform into an isolated periodic oscillatory switching waveform, said voltage transforming means selected from the group consisting of step down and step up and equal transformation ratios devices.

8. The AC line input low power isolated high frequency power supply as set forth in claim 1, wherein said voltage transforming means comprises a ferrite transformer with multiple output taps providing isolation ability having a primary side and multiple secondary sides said voltage transforming means producing said periodic oscillatory switching waveform into one or more an isolated periodic oscillatory switching waveforms, said voltage transforming means selected from the group consisting of step down and step up and equal transformation ratios devices or combinations of each.

9. The line operated low power isolated high frequency power supply as set forth in claim 1, comprising means for generating an isolated, rectified and filtered DC voltage component from an periodic oscillatory switching waveform, said rectifying and filtering means comprising:
a) a diode to receive and rectify said oscillatory switching waveform, and
b) a second capacitor to receive and filter the said rectified waveform.

10. An AC line operated low power isolated output high frequency power supply for generating either low, high or a combination of multiple voltages simultaneously, from one input AC voltage line magnitude, from an AC source comprising:
a) a bidirectionally conducting two state electronic device displaying either a high impedance off state or low impedance on state, coupled to the AC line for converting the incoming AC waveform through switching action, providing a periodic oscillatory waveform with high frequency components, said bidirectional two state electronic device having a breakover voltage Vbo, said bidirectional two state electronic device comprising a high impedance high voltage non-conducting first state when the applied voltage across its terminals is below Vbo, said bidirectional two state electronic device comprising a low impedance conducting second state when the applied voltage across its terminals reaches and exceeds the breakover voltage Vbo upon which said device suddenly switches between the high impedance and low impedance first and second states,
b) an energy coupling device for coupling high frequency electrical signals generated by said bi-directional two state electronic device, for coupling high frequency energy through series circuit, said energy coupling device has the property of accumulation of electronic charge with increase in applied voltage,
c) voltage transforming means coupled to said energy coupling device for converting oscillatory periodic waveforms to isolated periodic waveforms,
d) voltage rectification means coupled to said voltage transforming means for extraction of DC component,
e) voltage filtering means coupled to said voltage rectification means for reducing the AC ripple voltage component of said rectified component.

11. The AC line operated low power isolated high frequency power supply as set forth in claim 10, wherin said voltage transforming means comprises a high frequency ferrite transformer having a primary and isolated secondary or secondaries for generating an isolated transformed oscillatory periodic waveform at its secondary or secondaries when said oscillatory periodic waveform is applied to the primary.

12. The AC line operated low power isolated high frequency power supply as set forth in claim 10, wherein said voltage rectification means comprises a rectification technique utilizing a simple series diode arrangement.

13. The AC line operated low power isolated high frequency power supply as set forth in claim 10, wherein said voltage rectification and said filtering comprises a voltage multiplication technique.

14. The AC line operated low power isolated high frequency power supply as set forth in claim 10, wherein said voltage rectification technique utilizing a bridge rectifier or any combinations of diodes coupled to capacitor arrangement to achieve rectification and filtering of oscillatory periodic waveform.

15. The line operated low power isolated high frequency power supply as set forth in claim 10 ,wherin said voltage rectification means comprises a rectification technique utilizing means selected from the group consisting of half wave rectification and full wave rectification and voltage multiplication techniques.

16. The line operated low power isolated high frequency power supply as set forth in claim 10, wherein said voltage filtering means comprises a second charge storage device comprising a capacitor and converting said rectified periodic oscillatory waveform to a DC with minimum AC ripple component.

17. In a line operated isolated high frequency power supply, a method for generating low power voltages and currents comprising the steps of:
receiving and converting the incoming AC waveform to staircase switching waveforms using a bi-directional two state electronic device means of selected breakover voltage;
coupling the said staircase switching waveforms using a voltage controlled charge storage device enabling the bi-directional two state electronic device having a breakover voltage Vbo, to alternately switch conducting states in phase with the incoming AC line waveform,
converting said staircase switching waveforms into current pulses coupled to a voltage transforming means by use of said voltage controlled charge storage device,
transforming said current pulse to voltage pulses using a voltage transformation means which provides impedance to said current pulses, each current pulse resulting in high frequency isolated and transformed voltage pulse waveforms,
rectifying and filtering said transformed and isolated voltage pulse waveforms into a usable DC output potential, said DC output voltages and currents comprising said low power voltages and currents.

18. The method according to claim 17, wherein the step of generating said staircase switching waveforms comprises the coupling a bidirectional two state electronic device with selected breakover voltage, Vbo, to AC incoming line and said voltage controlled charge storage means, causing switching of the bi-directional two state electronic means thereby generating said staircase switching wave signals.

19. The method according to claim 17, wherein said voltage transforming means comprises a high frequency transformer having a primary and isolated secondary or multiple secondaries, said transformer producing said transformed and isolated voltage pulses at its secondary side.

20. The method according to claim 17, wherein said transformed and isolated voltage pulses are coupled to a rectification circuitry yield a DC voltage component.

21. The method according to claim 17, wherein said DC voltage component is filtered to remove AC ripple voltage.
